(19) United States
(12) Patent Application Publication
(10) Pub. No.: US 2015/0062835 A1
(43) Pub. Date: Mar. 5, 2015

(54) CIRCUIT MODULE

(71) Applicant: Taiyo Yuden Co., Ltd., Tokyo (JP)

(72) Inventors: Takehiko KAI, Tokyo (JP); Eiji MUGIYA, Tokyo (JP); Masaya SHIMAMURA, Tokyo (JP); Kenzo KITAZAKI, Tokyo (JP); Hiroshi NAKAMURA, Tokyo (JP); Tetsuo SAJI, Tokyo (JP)

(73) Assignee: Taiyo Yuden Co., Ltd., Tokyo (JP)

(21) Appl. No.: 14/102,241

(22) Filed: Dec. 10, 2013

(30) Foreign Application Priority Data
Sep. 3, 2013 (JP) 2013-182274

(51) Int. Cl. H05K 1/02; H05K 3/10

(52) U.S. Cl. CPC H05K 1/0216; H05K 3/10
USPC 361/748; 29/832

(57) ABSTRACT

A circuit module includes a wiring substrate having a mount surface that has first, second, and third areas; a plurality of electronic components mounted on the areas; an insulating sealing layer that has a main surface and a side surface and covers the plurality of electronic components, the main surface having a trench that is sequentially formed along a boundary between the areas to be diverged en route and has a tapered shape toward the mount surface, the side surface being formed around the main surface; and a conductive shield that has first and second shield portions and includes conductive resin, the first shield portion covering the side surface of the sealing layer and having a first thickness, the second shield portion being provided in the trench and having a second thickness larger than the first thickness at a height of half the total height of the second shield portion.

### CROSS-REFERENCE TO A RELATED APPLICATION

This application claims priority under 35 U.S.C. §119 to Japanese Patent Application No. JP 2013-182274 filed on Sep. 3, 2013, the entire content of which is hereby incorporated herein by reference in its entirety

### FIELD

The present disclosure relates to a circuit module having an electromagnetic shielding function.

### BACKGROUND

A circuit module in which a plurality of electronic components are mounted on a substrate, which is installed in various electronic apparatuses, has been known. In general, such a circuit module employs a configuration that has an electromagnetic shielding function to prevent an electromagnetic wave from leaking to the outside of the module and entering from the outside.

Furthermore, with diversification and high-functionalization of the electronic components mounted in the circuit module, various measures for preventing the electronic components from electromagnetically interfere with each other have been proposed. For example, Japanese Patent Application Laid-open No. 2010-225620 describes a circuit module in which a slit penetrating a mold resin layer to reach a circuit substrate is formed between two electronic components on the circuit substrate and the slit is filled with conductive resin.

### SUMMARY

In the configuration described in Japanese Patent Application Laid-open No. 2010-225620, however, it is difficult to fill with the conductive resin in the case where the width of the groove of the slit is narrow because the slit has a linear shape. On the other hand, if the width of the slit is widened, it causes a problem of reduction in mounting area of the electronic component.

In view of the circumstances as described above, it is desirable to provide a circuit module capable of improving the filling properties of conductive resin and securing a large mounting area of components while preventing internal interference.

According to an embodiment of the present disclosure, there is provided a circuit module including a wiring substrate, a plurality of electronic components, a sealing layer, and a conductive shield.

The wiring substrate has a mount surface, the mount surface having a first area and a second area.

The plurality of electronic components are mounted on the first area and the second area.

The sealing layer has a main surface and a side surface, the sealing layer including an insulating material, the insulating sealing layer covering the plurality of electronic components, the main surface having a trench, the trench being formed along a boundary between the first area and the second area, the trench having a tapered shape toward the mount surface, the side surface being formed around the main surface.

The conductive shield has a first shield portion and a second shield portion, the conductive shield including conductive resin, the first shield portion covering the side surface of the sealing layer with a first thickness, the second shield portion being provided in the trench. The second shield portion has a second thickness larger than the first thickness at a height of half the total height of the second shield portion.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIG. 1 is a plan view of a circuit module according to a first embodiment of the present disclosure;

FIG. 2 is a cross-sectional view taken along the direction of line A-A in FIG. 1;

FIG. 3 is an enlarged view of a main portion of the circuit module;

FIG. 4 is a diagram for explaining a method of producing the circuit module;

FIG. 5 is a plan view for explaining the method of producing the circuit module, showing a process of arranging electronic components;

FIGS. 6A and 6B are each a diagram for explaining the method of producing the circuit module, FIG. 6A is a plan view showing a process of forming a sealing layer, and FIG. 6B is a cross-sectional view of a main portion thereof;

FIGS. 7A and 7B are each a diagram for explaining the method of producing the circuit module, FIG. 7A is a plan view showing a half-cut process, and FIG. 7B is a cross-sectional view of a main portion thereof;

FIGS. 8A and 8B are each a diagram for explaining the method of producing the circuit module, FIG. 8A is a plan view showing a process of forming a trench, and FIG. 8B is a cross-sectional view of a main portion thereof;

FIGS. 9A and 9B are each a diagram for explaining the method of producing the circuit module, FIG. 9A is a plan view showing a process of forming a conductive shield, and FIG. 9B is a cross-sectional view of a main portion thereof;

FIGS. 10A and 10B are each a diagram for explaining the method of producing the circuit module, FIG. 10A is a plan view showing a dividing process, and FIG. 10B is a cross-sectional view of a main portion thereof;

FIG. 11 is a vertical cross-sectional view of a main portion of a circuit module according to a second embodiment of the present disclosure; and

FIG. 12 is an enlarged view of a main portion of FIG. 11.

### DETAILED DESCRIPTION OF EMBODIMENTS

A circuit module according to an embodiment of the present disclosure includes a wiring substrate, a plurality of electronic components, a sealing layer, and a conductive shield.

The wiring substrate has a mount surface, the mount surface having a first area and a second area.

The plurality of electronic components are mounted on the first area and the second area.

The sealing layer has a main surface and a side surface, the sealing layer including an insulating material, the insulating sealing layer covering the plurality of electronic components, the main surface having a trench, the trench being formed along a boundary between the first area and the second area, the trench having a tapered shape toward the mount surface, the side surface being formed around the main surface.

The conductive shield has a first shield portion and a second shield portion, the conductive shield including conductive resin, the first shield portion covering the side surface of the sealing layer with a first thickness, the second shield portion being provided in the trench. The second shield portion has a second thickness larger than the first thickness at a height of half the total height of the second shield portion.

The sealing layer has the trench having a tapered shape toward the mount surface. Accordingly, the conductive resin can be easily filled in the trench, and it is possible to increase the filling amount of conductive resin while securing a large mounting area of components. Therefore, it is possible to form a conductive shield capable of preventing an electromagnetic wave from entering and leaking from the module more effectively without increasing the size of the module.

The conductive shield has the second thickness of the second shield portion larger than the first thickness of the first shield portion. Accordingly, it is possible to prevent electromagnetic interference between the areas more effectively.

Here, the total height of the second shield portion typically represents the length of the second shield portion along a first axial direction perpendicular to the mount surface. On the other hand, in the case where another shield portion (third shield portion) connected to the second shield portion is provided, the total height of the second shield portion represents the total height including the connection portion between these shield portions. Furthermore, the second thickness represents the length of the second shield portion along a second axial direction perpendicular to the first axial direction. Typically, the second thickness corresponds to the facing distance between both side walls of the trench (groove width) at the height position.

Although the first shield portion has a uniform thickness in a height direction, it is not limited thereto, of course. For example, the first shield portion may have a tapered shape toward the mount surface. Accordingly, it is possible to prevent an electromagnetic wave from entering and leaking from the area covered by the conductive shield more effectively without increasing the size of the module while securing a large mounting area of components. In this case, the width at a height of half the total height of the first shield portion corresponds to the first thickness.

The conductive shield may further have a third shield portion covering the main surface, which is connected to the first and second shield portions. Accordingly, it is possible to prevent an electromagnetic wave from entering and leaking from the area covered by the conductive shield more effectively.

The wiring substrate may further have a conductor pattern formed along the boundary, and the trench may have a maximum depth corresponding to a distance between the main surface and a surface of the conductor pattern. Accordingly, the depth of the trench becomes a maximum depth such that the conductive shield sufficiently functions, and it is possible to reduce the excess amount of conductive resin to be used due to deeper depth of the trench. It is possible to increase the contact area between a second shield portion 52 and a conductor pattern 10 exposed from the bottom of a trench 41, and to ensure reliable electrical connection between the conductor pattern 10 and the second shield portion 52.

The trench may be formed by laser processing. The type of the processing laser is not particularly limited. Examples of the processing laser include an Nd:YAG laser, an Nd:YVO₄ laser, and a CO₂ laser. Accordingly, it is possible to form the boundary to have an arbitrary shape.

Hereinafter, embodiments according to the present disclosure will be described with reference to the drawings.

### First Embodiment

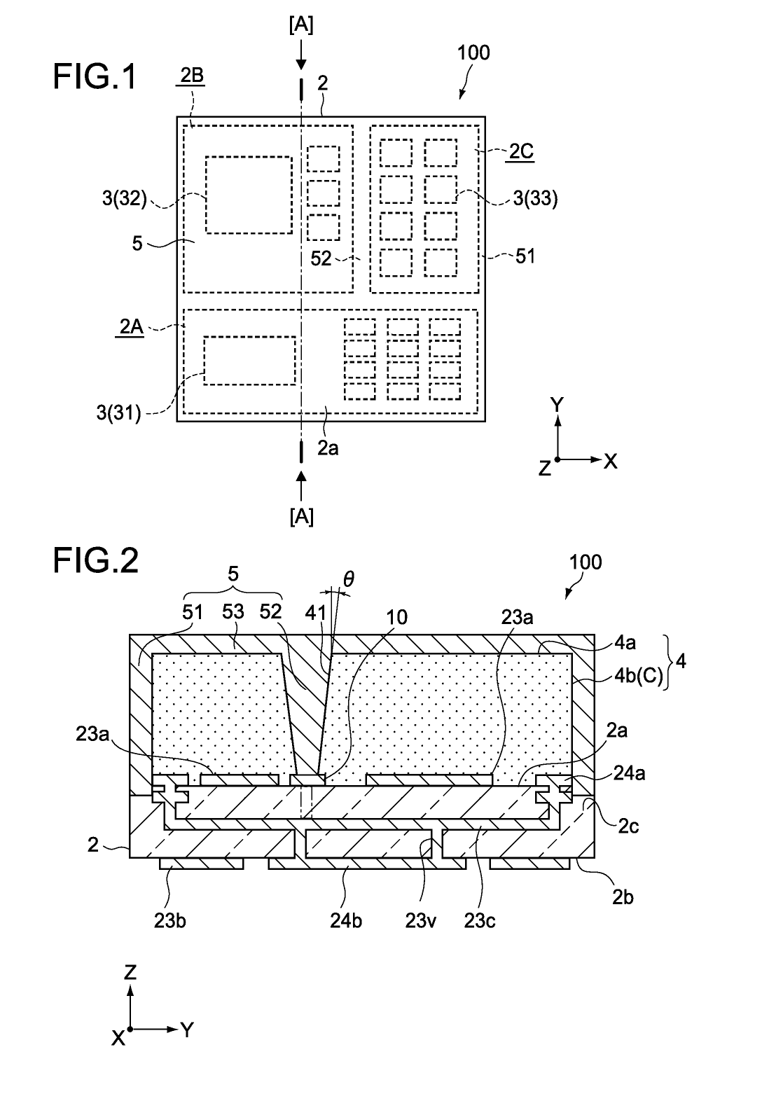

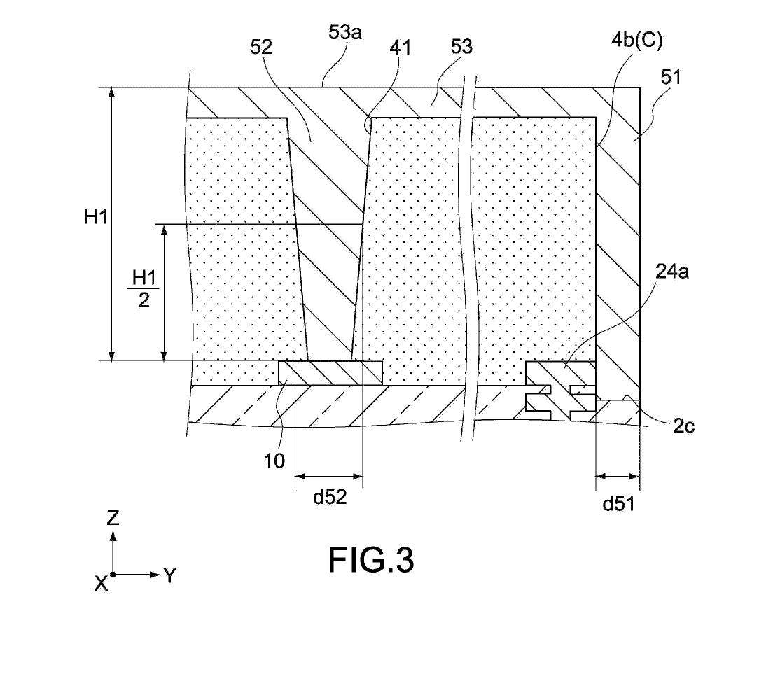

FIGS. 1 to 3 are each a diagram showing a circuit module according to an embodiment of the present disclosure. FIG. 1 is a top view, FIG. 2 is a cross-sectional view taken along the direction of line A-A in FIG. 1, and FIG. 3 is an enlarged cross-sectional view of a main portion of FIG. 2.

It should be noted that in each figure, X-, Y-, and Z-axes represent triaxial directions orthogonal to each other, and the Z-axis direction corresponds to the thickness direction of the circuit module. It should be noted that the configuration of each portion is exaggeratingly shown in order to facilitate understanding, and the sizes of the members or the ratios of the sizes of the members do not necessarily correspond to each other in the figures.

In this embodiment, the assumption is made that a length along the Z-axis direction is a height, and a length along in the second axial direction perpendicular to the Z-axis direction is a width.

A circuit module 100 according to this embodiment includes a wiring substrate 2, a plurality of electronic components 3 (31 to 33), a sealing layer 4, and a conductive shield 5.

The circuit module 100 is formed in a substantially rectangular parallelepiped shape as a whole. The size of the circuit module 100 is not particularly limited, and the circuit module 100 is formed to have the length of 10 to 50 mm along the X-axis direction and the length of 10 to 50 mm along the Y-axis direction, for example. In this embodiment, the circuit module 100 is formed to have a substantially square shape having a side length of about 35 mm. Moreover, also the thickness of the circuit module 100 is not particularly limited, and the circuit module 100 is formed to have the thickness of 1 to 3 mm, for example. In this embodiment, the circuit module 100 is formed to have the thickness of about 2 mm.

In the circuit module 100, the plurality of electronic components 3 are disposed on the wiring substrate 2, and the sealing layer 4 and the conductive shield 5 are formed so as to cover them. Hereinafter, the configuration of the respective portions of the circuit module 100 will be described.

### (Wiring Substrate)

The wiring substrate 2 includes a mount surface 2a formed to have a substantially square shape, which has the same size as the entire circuit module 100, and a terminal surface 2b formed on the opposite side of the mount surface 2a, for example. The wiring substrate 2 includes a glass epoxy multilayer wiring substrate having the thickness of about 0.4 mm, for example. The material forming the insulating layer of the wiring substrate 2 is not limited to the above-described glass epoxy material, and an insulating ceramic material can be employed, for example.

The wiring layer of the wiring substrate 2 typically includes a conductive material such as Cu, and is disposed on the surface, rear surface, and inner layer of the wiring substrate 2. The wiring layer is subjected to patterning into a predetermined shape to form an upper layer wiring pattern 23a disposed on the mount surface 2a, a lower layer wiring pattern 23b disposed on the terminal surface 2b, and an inner layer wiring pattern 23c disposed therebetween. The upper layer wiring pattern 23a includes a land portion on which the electronic component 3 is mounted, and the conductor pattern 10 connected to the second shield portion 52 (conductive shield 5). The lower layer wiring pattern 23b includes an external connection terminal connected to a control substrate (an illustration omitted) of the electronic apparatus on which the circuit module 100 is mounted. The layers of the wiring layer are electrically connected to each other via a via conductor 23v.

Moreover, the above-mentioned wiring layer includes a first GND terminal 24a and a second GND terminal 24b, which are connected to a ground (GND) potential. The first GND terminal 24a is disposed adjacent to an uneven surface 2c formed around the upper surface of the wiring substrate 2, and is connected to the inner surface of a first shield portion 51 (conductive shield 5) disposed on the uneven surface 2c. The first GND terminal 24a may be formed as a part of the upper layer wiring pattern 23a, or a part of the inner layer wiring pattern 23c.

The second GND terminal 24b is connected to the first GND terminal 24a via the inner layer wiring pattern 23c. The second GND terminal 24b is formed as a part of the lower layer wiring pattern 23b, and is connected to a ground wiring of the above-mentioned control substrate.

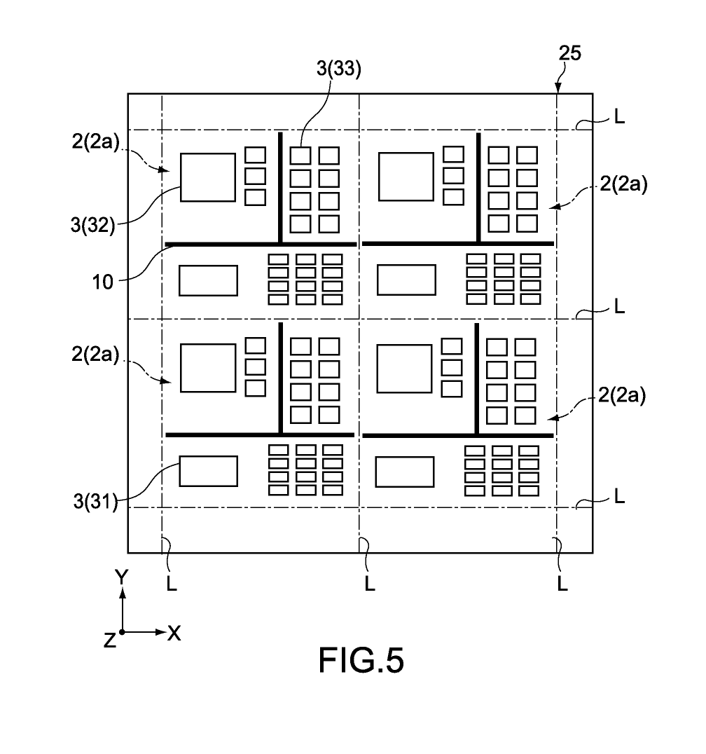

The mount surface 2a is divided into a plurality of areas by the second shield portion 52 (conductive shield 5), and includes a first area 2A, a second area 2B, and a third area 2C, in this embodiment. In the example shown in FIG. 1, the first to third areas 2A to 2C are formed to have different sizes and different rectangular shapes. However, the areas 2A to 2C may be formed to have another polygon shape such as a triangular shape and a pentagonal shape, a circular shape, or an arbitrary geometric shape such as an elliptical shape. Moreover, the number of areas partitioned on the mount surface 2a is not limited to three, and may be two or not less than four. The conductor pattern 10 is formed along the boundary between the first to third areas 2A to 2C (FIG. 5).

### (Electronic Component)

The plurality of electronic components 3 are mounted on the first, second, and third areas 2A, 2B, and 2C on the mount surface 2a. Typically, examples of the plurality of electronic components 3 include various components such as an integrated circuit (IC), a capacitor, an inductor, a resistor, a crystal oscillator, a duplexer, a filter, and a power amplifier.

These components include components that generate an electromagnetic wave around them during operation or components liable to be affected by the electromagnetic wave. Typically, these components are mounted on different areas partitioned by the second shield portion 52 (conductive shield 5). Hereinafter, the electronic component 3 and the plurality of electronic components 3 mounted on the first area 2A are also referred to as electronic component 31, and the electronic component 3 and the plurality of electronic components 3 mounted on the second area 2B are also referred to as electronic component 32. Then, the electronic component 3 and the plurality of electronic components 3 mounted on the third area 2C are also referred to as electronic component 33.

The plurality of electronic components 3 are typically mounted on the mount surface 2a by soldering, an adhesive, an anisotropy adhesive sheet, a bonding wire, or the like.

### (Sealing Layer)

The sealing layer 4 includes an insulating material formed on the mount surface 2a so as to cover the plurality of electronic components 31 and 32. The sealing layer 4 is divided into a first area 2A side, a second area 2B side, and a third area 2C side by the second shield portion 52. In this embodiment, the sealing layer 4 includes insulating resin such as epoxy resin to which silica or alumina is added. The method of forming the sealing layer 4 is not particularly limited, and the sealing layer 4 is formed by a molding method, for example.

The sealing layer 4 has a main surface 4a and four side surfaces 4b. The main surface 4a has the trench 41 formed along the boundary between the first area 2A, the second area 2B, and the third area 2C. The four side surfaces 4b are formed around the main surface 4a. The main surface 4a corresponds to the upper surface of the sealing layer 4, and the side surfaces 4b correspond to peripheral surfaces of the sealing layer 4. The trench 41 is formed along the height direction (Z-axis direction) from the main surface 4a of the sealing layer 4 to have a predetermined depth. In this embodiment, the trench 41 is formed to have a depth such that the bottom surface of the trench 41 reaches the surface of the conductor pattern 10 disposed on the mount surface 2a (see FIG. 2).

The trench 41 has a tapered shape toward the surface of the conductor pattern 10 from the main surface 4a of the sealing layer 4. The angle θ between the side surface of the trench 41 and the depth direction of the trench 41 (Z-axis direction) is not particularly limited. If the angle θ is extremely small, it is difficult to fill the conductive resin in the trench. On the other hand, if the angle θ is extremely large, it is difficult to mount electronic components around the trench. The angle θ can be appropriately set depending on the width, depth, or the like of the trench 41. Moreover, the side surface of the trench 41 is not limited to a linear inclined surface, and may be a curved surface.

The method of forming the trench 41 is not particularly limited. However, in this embodiment, the trench 41 is formed by a laser processing technique. The laser for processing is not particularly limited. However, in this embodiment, an Nd:YAG laser (having a wavelength of 1064 nm) is used as the laser for processing.

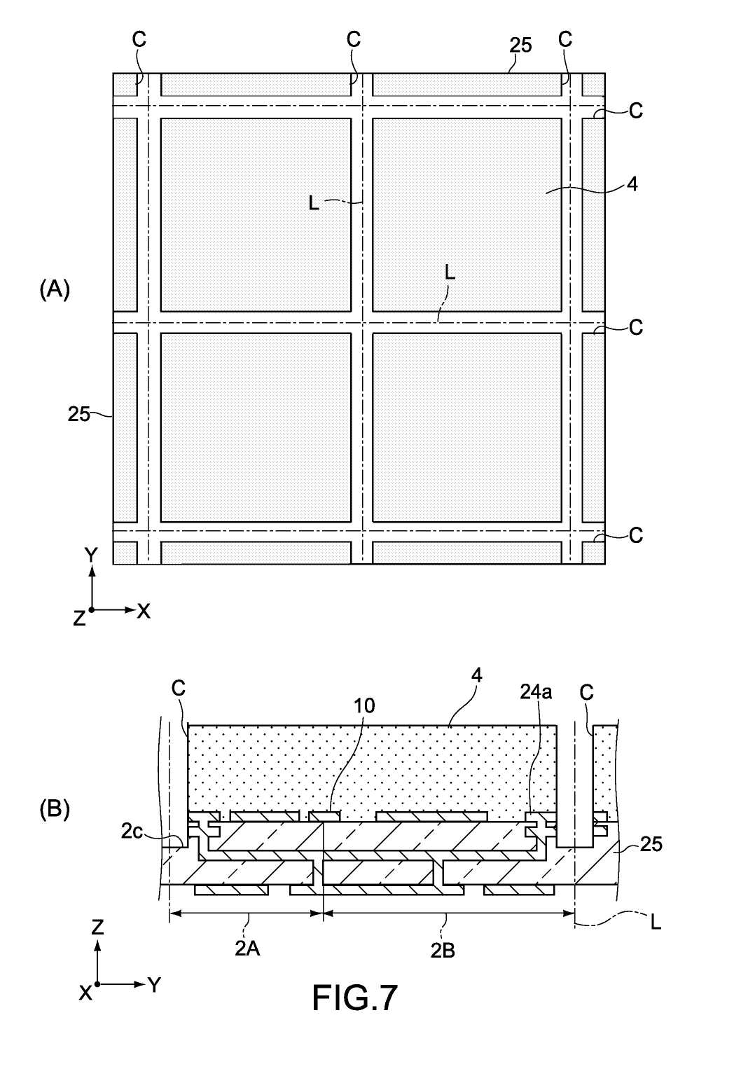

The side surface 4b formed around the main surface 4a of the sealing layer 4 includes a side surface of a cut groove C having a depth reaching the inside of an aggregate substrate 25. The cut groove C includes a separated groove provided in the sealing layer 4 in a process of producing the circuit module 100, as will be described later (FIG. 7A). The method of forming the cut groove C is not particularly limited. In this embodiment, the cut groove C is formed by using a dicer, for example. The cut groove C has a groove shape having a uniform thickness in the height direction.

### (Conductive Shield)

In this embodiment, the conductive shield 5 has a first shield portion 51, the second shield portion 52, and a third shield portion 53. The first shield portion 51 and the third shield portion 53 are formed so as to cover the four side surfaces 4b of the sealing layer 4 and the main surface 4a of the sealing layer 4, respectively, and function as the exterior shield of the circuit module 100. The second shield portion 52 is provided in the trench 41 of the sealing layer 4 and functions as the interior shield of the circuit module 100.

It should be noted that the third shield portion 53 may be omitted as necessary, or may be formed on only a part of the main surface 4a. Alternatively, the third shield portion 53 may be formed as a display unit for displaying the type or the like of the circuit module 100.

The first shield portion 51 is formed on each side surface of the sealing layer 4. In this embodiment, the first shield portion 51 has a uniform thickness d51 (first thickness) in the height direction, covers the uneven surface 2c of the wiring substrate 2, and is electrically connected to the first GND terminal 24a. On the other hand, the second shield portion 52 has a shape corresponding to the shape of the trench 41, i.e., tapered shape from the main surface 4a of the sealing layer 4 toward the conductor pattern 10.

As shown in FIG. 3, the length of the second shield portion 52 along the Z-axis direction is assumed to be a total height H1, and a length along the Y-axis at the height of half the total height H1 (H1/2) is defined as a reference thickness d52 of the second shield portion 52 (second thickness). In this embodiment, the total height H1 of the second shield portion 52 corresponds to the height from the surface of the conductor pattern 10 to an upper surface 53a of the third shield portion 53 disposed right above the second shield portion 52.

In this embodiment, the reference thickness d52 of the second shield portion 52 is formed to be larger than the thickness d51 of the first shield portion 51. Accordingly, it is possible to prevent electromagnetic interference between a plurality of electronic components in the module more effectively.

Moreover, because the second shield portion 52 has a tapered shape from the main surface toward the surface of the conductor pattern, the filling efficiency of conductive resin is improved. Accordingly, it is possible to improve the workability. Furthermore, it is possible to increase the filling amount of conductive resin to the degree that electromagnetic interference between the plurality of electronic components in the module can be prevented while securing a large mounting area of components.

The thickness d51 of the first shield portion 51 and the reference thickness d52 of the second shield portion 52 are not particularly limited, and only have to satisfy the relationship d51<d52. Specifically, in this embodiment, the first shield portion 51 and the second shield portion 52 are formed so that d51 is 0.07 mm and d52 is 0.15 mm.

The conductive shield 5 includes a cured conductive resin material filled in the outer surface of the sealing layer 4 and in the trench 41. More specifically, epoxy resin to which conductive particles such as Ag and Cu are added is employed as the material of the conductive shield 5. Alternatively, the conductive shield 5 may include a plated layer or sputtered layer deposited on the outer surface of the sealing layer 4 and the inner wall of the trench 41.

With such a configuration, it is possible to form the first shield portion 51, the second shield portion 52, and the third shield portion 53 in the same process. Moreover, it is possible to integrally form the first shield portion 51, the second shield portion 52, and the third shield portion 53.

### [Method of Producing Circuit Module]

Next, a method of producing the circuit module 100 according to this embodiment will be described.

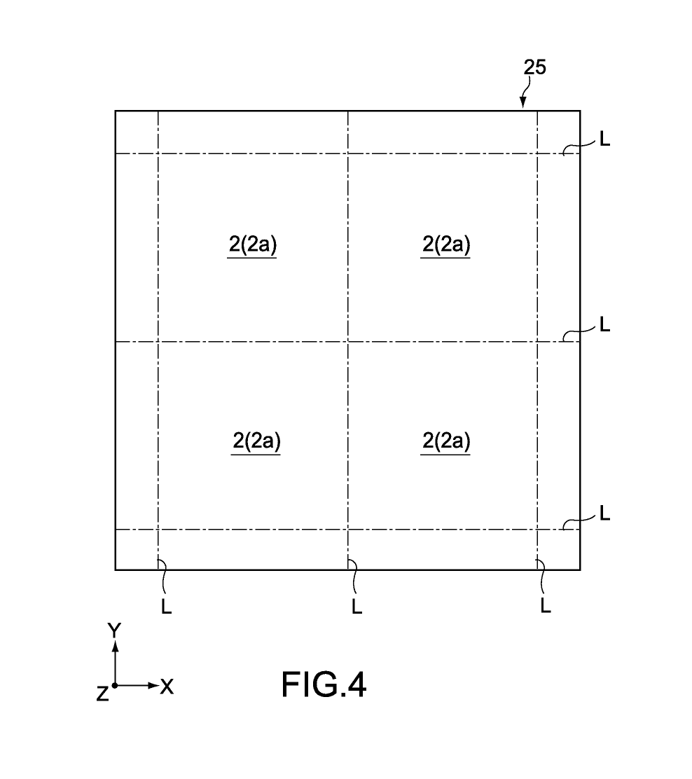

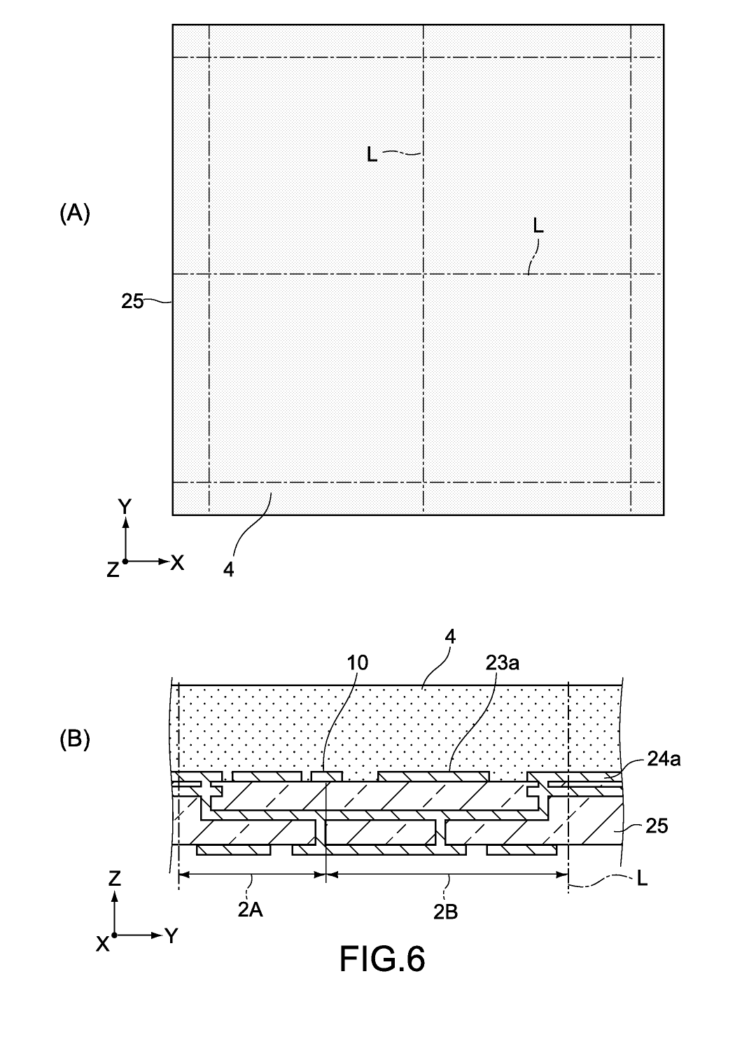

FIGS. 4 to 10 are diagrams for explaining a method of producing the circuit module 100. Moreover, in FIGS. 6 to 10, A is a top view and B is a cross-sectional view of a main portion viewed from the X-axis direction. The method of producing the circuit module according to this embodiment includes a process of preparing an aggregate substrate, a process of mounting an electronic component, a process of forming a sealing layer, a half-cut process, a process of forming a trench, a process of forming a conductive shield, and a cutting process. Hereinafter, each process will be described.

### (Process of Preparing Aggregate Substrate)

FIG. 4 is a top view schematically showing the configuration of the aggregate substrate 25. The aggregate substrate 25 includes a substrate with a large area on which a plurality of wiring substrates 2 are attached. FIG. 4 shows separation lines L dividing the plurality of wiring substrates 2. The separation line L may be a virtual line, and drawn on the aggregate substrate 25 actually by printing or the like.

On the aggregate substrate 25, the conductive shield 5 is finally formed through each process to be described later. In the cutting process being the last process, the aggregate substrate 25 is cut (full-cut) along the separation line L to produce a plurality of circuit modules 100. Moreover, although not shown, in the aggregate substrate 25, a predetermined wiring pattern is formed for each area forming the wiring substrate 2.

It should be noted that in the example shown in FIG. 4, an example in which four wiring substrates 2 are cut from the aggregate substrate 25 is shown. The number of wiring substrates 2 to be cut is not particularly limited. For example, in the case where a substrate formed to have a substantially square shape of about 150 mm square is used as the aggregate substrate 25, four wiring substrates 2 of about 35 mm square are arranged in the X-axis direction and the Y-axis direction, i.e. sixteen wiring substrates 2 are arranged. Moreover, as the aggregate substrate 25, a substrate having a rectangular shape 100 to 200 mm on a side is typically used.

### (Process of Mounting Electronic Component)

FIG. 5 is a diagram for explaining a process of mounting the electronic components 3 (31 to 33), and show a mode in which the electronic components 31 to 33 are disposed on the aggregate substrate 25 (wiring substrate 2).

In this process, the plurality of electronic components 31 to 33 are mounted on the first area 2A, the second area 2B, and the third area 2C on the mount surface 2a. As the method of mounting the electronic components 31 to 33, a reflow process is employed, for example. Specifically, first, a soldering paste is applied to a predetermined land portion on the mount surface 2a by printing or the like. Next, the plurality of electronic components 31 to 33 are mounted on the predetermined land portion via the soldering paste. After that, the aggregate substrate 25 on which the electronic components 31 to 33 are mounted is put in a reflow furnace, and the electronic components 31 to 33 are electrically and mechanically bonded to the mount surface 2a by performing a reflow process on the soldering paste.

### (Process of Forming Sealing Layer)

FIGS. 6A and 6B are diagrams for explaining a process of forming the sealing layer 4, and show a mode in which the sealing layer 4 is formed on the mount surface 2a.

The sealing layer 4 is formed on the mount surface 2a of the aggregate substrate 25 so as to cover the plurality of electronic components 31 to 33. The method of forming the sealing layer 4 is not particularly limited, and a molding method using a mold, a potting molding method using no mold, or the like can be applied, for example. Moreover, after a liquid or paste sealing resin material is applied to the mount surface 2a by a spin coating method or a screen printing method, heat treatment may be applied on it to be cured.

### (Half-Cut Process)

FIGS. 7A and 7B are diagrams showing a half-cut process. In this process, cut grooves C are formed along the separation line L to have a depth ranging from the main surface 4a of the sealing layer 4 to the inside of the aggregate substrate 25 by a dicer, for example. The cut groove C forms the uneven surface 2c of the aggregate substrate 25 (wiring substrate 2). The depth of the cut groove C is not particularly limited. However, the cut groove C is formed to have a depth such that the first GND terminal 24a on the aggregate substrate 25 can be divided.

### (Process of Forming Trench)

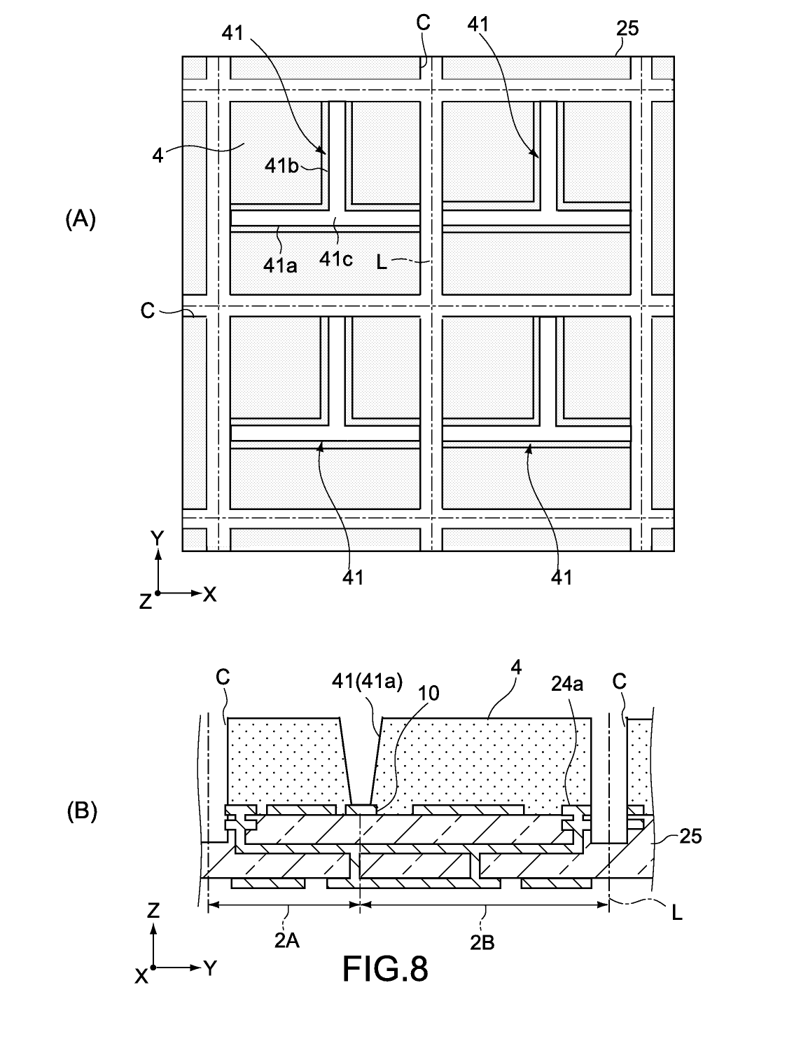

FIGS. 8A and 8B are diagrams for explaining a process of forming the trench 41. The trench 41 is sequentially formed along the boundary between the areas 2A to 2C on the mount surface 2a so as to be diverged en route. Specifically, the trench 41 has a trench 41a formed along the boundary between the first area 2A and the second and third areas 2B and 2C, a second trench 41b formed along the boundary between the second area 2B and the third area 2C, and a diverging point 41c of the trench 41a and the trench 41b.

The tapered angle or aperture width of the trench 41 is not particularly limited, and may be set depending on the groove width of the cut groove C. For example, the tapered angle (θ) or aperture width of the trench 41 is set so that the width of the trench 41 at a height of half the total height is equal to or larger than half the width of the cur groove C.

The trench 41 is typically formed to have the same depth as the sealing layer 4. In this embodiment, the trench 41 is formed to have the maximum depth corresponding to the distance between the main surface 4a of the sealing layer 4 and the surface the conductor pattern 10. Accordingly, the trench 41 having a depth such that the surface of the conductor pattern 10 is exposed to the sealing layer 4 is formed along the boundary between areas 2A to 2C.

The method of forming the trench 41 is not particularly limited, and typically laser processing is employed. Accordingly, it is possible to easily form the trench 41 having a tapered shape from the main surface 4a of the sealing layer 4 toward the mount surface 2a.

The type of the laser beam is not particularly limited. In this embodiment, for example, an Nd—YAG is used. The laser beam may be a continuous wave or a pulse wave. The laser beam is applied, from the side of the upper surface of the sealing layer 4, to the area in which the second shield portion 52 is formed. The resin material of the area to be irradiated with the laser beam is removed by being partially molten or evaporated. The laser beam is scanned on the upper surface of the sealing layer 4 at constant power and speed, for example. Thus, the trenches 41 are formed to have almost equal depths. The number of times of scanning is not limited to one, and the scanning may be performed a plurality of times.

The method of forming the trench 41 is not limited to the laser processing, and another processing method such as a cutting method and a wire cutting method may be applied as long as the trench having the tapered shape can be formed.

The procedure for forming the trench 41 is not particularly limited. The second trench 41b may be formed after the first trench 41a is formed, or the first trench 41a may be formed after the second trench 41b is formed. Moreover, the trench 41 may be formed prior to the half-cut process.

### (Process of Forming Conductive Shield)

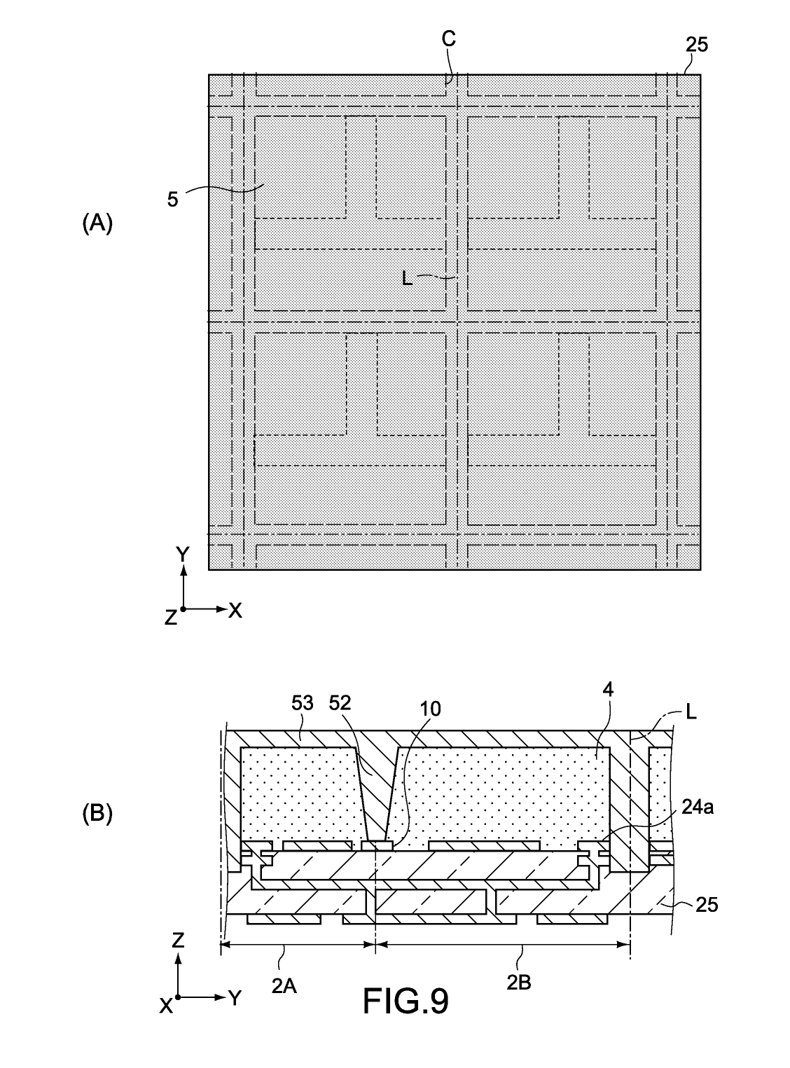

FIGS. 9A and 9B are diagrams for explaining a process of forming the conductive shield 5. The conductive shield 5 is formed on the sealing layer 4. Accordingly, the second shield portion 52 provided in the trench 41 and the third shield portion 53 covering the main surface 4a of the sealing layer 4 are formed. Moreover, the aggregate substrate 25 is full-cut along the separation line L in the cutting process being a later process, thereby forming the first shield portion 51 covering each side surface 4b of the sealing layer 4.

In this embodiment, the conductive shield 5 is formed by applying or filling conductive resin or conductive paint to/on the surface of the sealing layer 4. The method of forming the conductive shield 5 is not particularly limited, and a molding method using a mold, a potting molding method using no mold, or the like can be applied, for example. Moreover, after a liquid or paste sealing resin material is applied to the sealing layer 4 by a spin coating method or a screen printing method, heat treatment may be applied on it to be cured. Moreover, in order to improve the efficiency of filling the conductive material in the trench 41, the process may be performed in a vacuum atmosphere.

The second shield portion 52 is filled in the trench 41 formed in the process of forming the trench, and becomes a conductive shield having a tapered shape from the main surface 4a of the sealing layer 4 toward the surface of the conductor pattern 10. Accordingly, the second shield portion 52 is bonded to the surface of the conductor pattern 10, which is exposed at the bottom of the trench 41. In this embodiment, because the first shield portion 51, the second shield portion 52, and the third shield portion 53 include the same material, electrical conduction between the shield portions and a desired joint strength between the shield portions are ensured.

The conductive resin forming the conductive shield 5 is filled in also the cut groove C formed in the sealing layer 4, and forms the first shield portion 51 in the cutting process being a later process. Thus, the first shield portion 51 and the third shield portion 53 are electrically connected to the first GND terminal 24a on the substrate 2 facing the cut groove C. Accordingly, the first shield portion 51 and the first GND terminal 24a are electrically and mechanically connected to each other.

The forming of the conductive shield 5 may be performed by a vacuum deposition method such as a plating method and a sputtering method. In the plating method, by immersing the aggregate substrate 25 in a plating bath and depositing a plated layer on the outer surface of the sealing layer 4 and the inner wall surface of the trench 41, it is possible to form the conductive shield 5. In the sputtering method, by putting the aggregate substrate 25 in a vacuum chamber and sputtering a target including a conductive material to deposit a sputtered layer on the outer surface of the sealing layer 4 and the inner wall surface of the trench 41, it is possible to form the conductive shield 5. In this case, there is no need to fill the trench 41 with the plated layer or the sputtered layer.

### (Cutting Process)

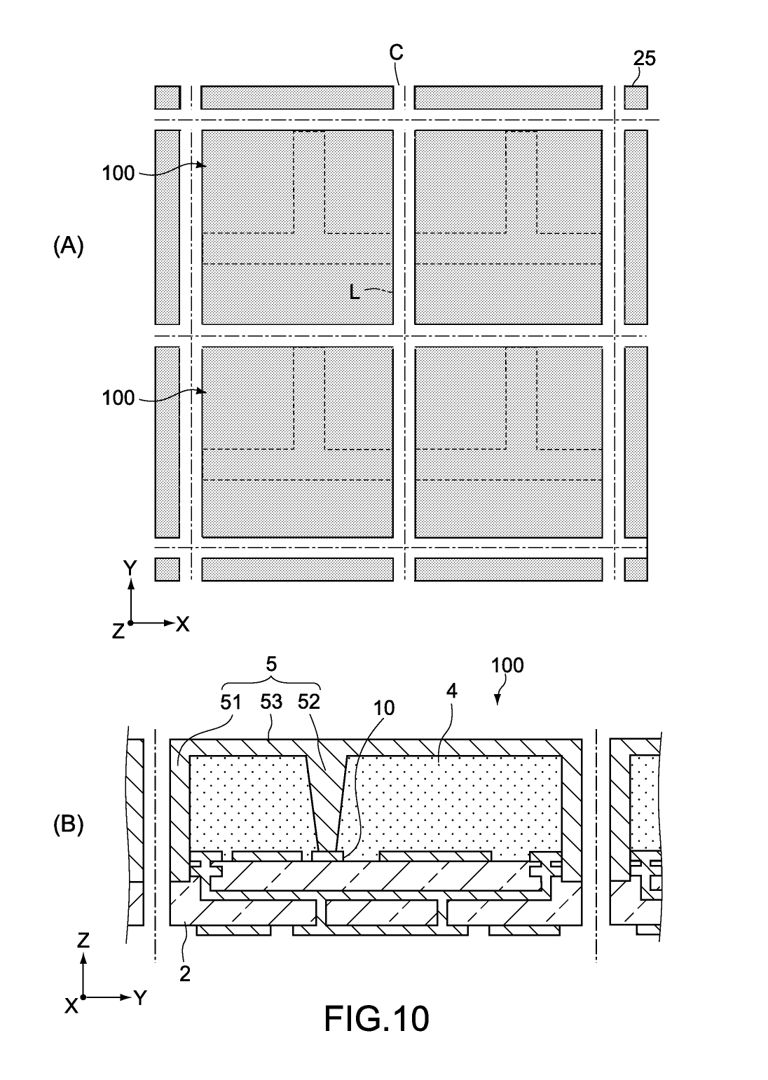

FIGS. 10A and 10B are diagrams for explaining a cutting process. In this process, the aggregate substrate 25 is full-cut along the separation line L, and thus divided into a plurality of circuit modules 100. For the separation, a dicer or the like is used. In this embodiment, because the conductive shield 5 is filled in the cut groove C, the aggregate substrate 25 is separated along the separation line L so that the wiring substrate 2 and the conductive shield 5 (first shield portion 51) have the same cut surface. Accordingly, the circuit module 100 including the conductive shield 5, which covers the surface of the sealing layer 4 and a part of the side surface of the wiring substrate 2, is produced.

[Operation of this Embodiment]

Through the above-mentioned processes, the circuit module 100 is produced. According to the method of producing a circuit module according to this embodiment, it is possible to produce the circuit module 100 including the conductive shield 5 having the first shield portion 51 and third shield portion 53, which prevents an electromagnetic wave from leaking to the outside of the module and entering from the outside, and the second shield portion 52 preventing electromagnetic interference between the plurality of electronic components in the module.

According to this embodiment, because the shield portion 52 is formed so that the reference thickness d52 of the second shield portion 52 is larger than the thickness d51 of the first shield portion 51, it is possible to prevent electromagnetic interference between the areas in the module more effectively.

Moreover, according to this embodiment, because the trench 41 formed in the sealing layer 4 has a tapered shape from the main surface 4a of the sealing layer 4 toward the surface of the conductor pattern 10, it is possible to easily fill the conductive resin in the trench 41. Furthermore, it is possible to increase the filling amount of conductive resin while securing a large mounting area of components. Accordingly, it is possible to prevent an electromagnetic wave from entering and leaking from the area covered by the second shield portion 52 and the third shield portion 53 and electromagnetic interference between the plurality of electronic components or the areas 2A to 2C in the module more effectively while reducing the size of the module.

Moreover, in the case where a material having relatively high heat conductivity is used as the conductive material forming the conductive shield 5, heat in the module is effectively transmitted to the outside of the module via the first shield portion 51. Accordingly, it is possible to form a circuit module having high heat radiation properties.

Moreover, because the trench 41 has the maximum depth corresponding to the distance between the main surface 4a of the sealing layer 4 and the surface of the conductor pattern 10, it is possible to increase the contact area between the second shield portion 52 and the conductor pattern 10 exposed from the bottom of the trench 41 and to ensure reliable electrical connection between the conductor pattern 10 and the second shield portion 52.

Moreover, the thickness d51 of the first shield portion can be adjusted by the thickness of a dicing saw in the cutting process. Accordingly, it is possible to set the tapered angle or aperture width of the trench 41 and the width of the cut groove C to an arbitrary value to form the first and second shield portions and to establish the relationship d51<d52 in the cutting process.

Moreover, according to this embodiment, because a laser processing method is employed for forming the boundary between the areas 2A, 2B, and 2C (trench 41) of the sealing layer 4 on which the second shield portion 52 is provided, the boundary is formed to have an arbitrary shape (e.g., bent shape, zigzag shape, and curved shape) as compared with the case where the boundary is formed by a dicing process. Accordingly, the degree of freedom of designing of the second shield portion 52 is increased.

### Second Embodiment

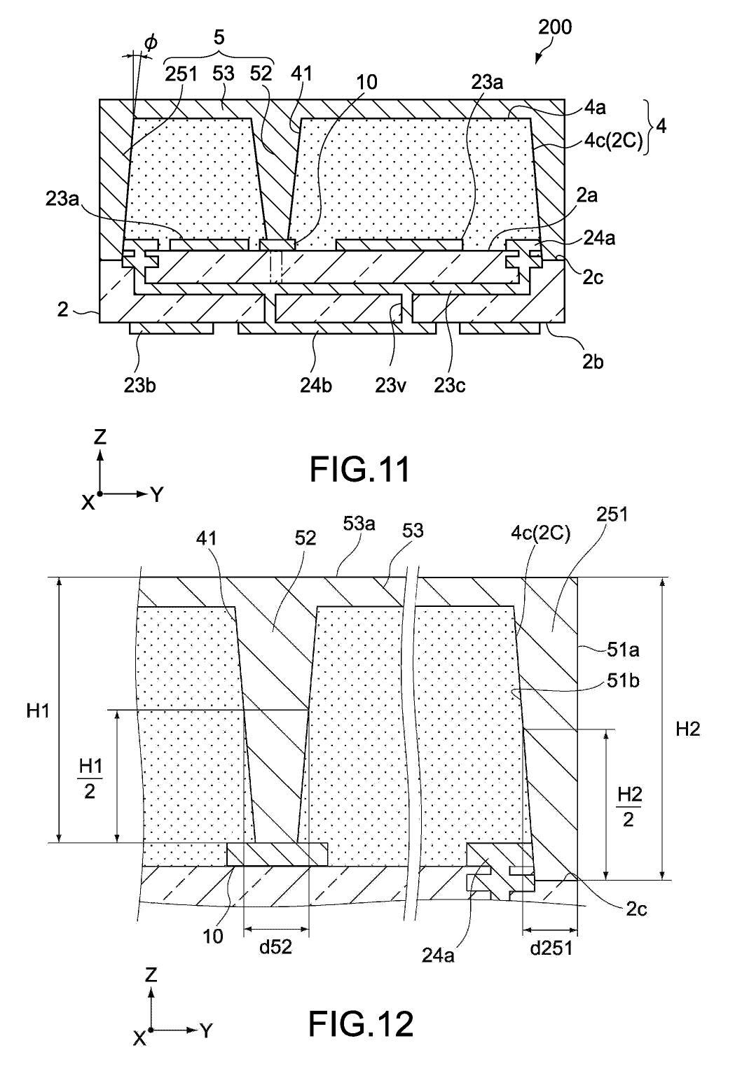

FIGS. 11 and 12 are cross-sectional views of a main portion showing a circuit module according to a second embodiment of the present disclosure. FIG. 11 is a vertical cross-sectional view of a main portion of the circuit module, and FIG. 12 is an enlarged view of a main portion of FIG. 11. Hereinafter, the configuration different from that of the first embodiment will be mainly described, and the same configuration as that according to the above-mentioned embodiment will be denoted by the same reference symbols and a description thereof will be omitted or simplified.

A circuit module 200 according to this embodiment has a configuration in which the shape of the first shield portion formed on each side surface of the sealing layer 4 is different from that in the first embodiment.

As shown in FIG. 12, the circuit module 200 according to this embodiment includes the conductive shield 5 having a first shield portion 251 covering the side surfaces 4c of the sealing layer 4, the second shield portion 52 provided in the trench 41, and the third shield portion 53 covering the main surface 4a. The first shield portion 251 has an outside surface 51a parallel to the height direction (Z-axis direction) and an inside surface 51b facing the side surface 4c of the sealing layer 4, and is formed so that the inside surface 51b is inclined with respect to the height direction (Z-axis direction) by an angle φ, i.e., the inside surface 51b is a tapered surface. Therefore, the first shield portion 251 has a tapered shape toward the uneven surface portion 2c. The first shield portion 251 covers the uneven surface portion 2c of the wiring substrate 2 and is electrically connected to the first GND terminal 24a. It should be noted that the first shield portion 251 has the same form in each side surface 4c of the sealing layer 4.

As in the first embodiment, the conductive shield 5 includes cured conductive paste. In this embodiment, each side surface 4c of the sealing layer 4 is formed to be a tapered surface obliquely inclined with respect to the uneven surface portion 2c of the wiring substrate 2 from the main surface 4a, and the inside surface 51b of the first shield portion 251 covering each side surface 4c is formed so as to copy the shape of the side surface 4c. Therefore, it is possible to adjust the inclined angle φ of the inside surface 51b by an inclined angle of the side surface 4c of the sealing layer 4.

Here, an assumption is made that the length of the first shield portion 251 along the Z-axis direction is a total height H2. In this embodiment, the total height H2 corresponds to the height from the uneven surface portion 2c to the upper surface 53a of the third shield portion 53 disposed right above the first shield portion 251, and the length along the Y-axis direction at the height of half the total height H2 (H2/2) is defined as a reference thickness d251 (first thickness) of the first shield portion 251.

In this embodiment, the reference thickness d52 of the second shield portion 52 is larger than the reference thickness d251 of the first shield portion 251, and the first shield portion 251 has a tapered shape toward the uneven surface portion 2c. Therefore, it is possible to prevent an electromagnetic wave from entering and leaking from the area covered by the first shield portion 251 and the third shield portion 53 without increasing the size of the module while preventing electromagnetic interference between the plurality of electronic components in the module more effectively.

Next, a method of producing the circuit module 200 will be described. It should be noted that because the process of preparing an aggregate substrate, the process of mounting electronic components, the process of forming a sealing layer, the process of forming a trench, and the cutting process are same as those in the first embodiment, a description thereof will be omitted here.

In this embodiment, the first shield portion 251 is formed through the half-cut process and the process of forming the conductive shield.

In the half-cut process according to this embodiment, the cut groove 2c is formed along the separation line L by laser processing, for example. Accordingly, the cut groove 2C is formed to have a tapered shape from the main surface 4a of the sealing layer 4 toward the uneven surface portion 2c. The angle φ between the side surface 4c of the sealing layer 4 and the depth direction of the cut groove 2C (Z-axis direction) is not particularly limited. However, if the angle is extremely small, it is difficult to fill the conductive resin in the groove portion. On the other hand, if the angle is extremely large, it is difficult to mount the electronic components in the vicinity of the trench. Moreover, the side surface 4c of the sealing layer 4 is not limited to a linear inclined surface, and may have a curved surface shape.

Moreover, the method of forming the cut groove 2C is not limited to the laser processing, and another processing method such as a cutting method and a wire cutting method may be applied as long as the trench having the tapered shape can be formed.

In the process of forming the conductive shield according to this embodiment, the first shield portion 251 is filled in the cut groove 2C formed in the half-cut process, and is formed by full-cutting the aggregate substrate 25 along the separation line L in the cutting process being a later process. Accordingly, the conductive shield 5 including the first shield portion 251 having the outside surface 51a and the inside surface 51b. The outside surface 51a has a linear shape along the Z-axis direction. The inside surface 51b has the tapered shape copying the shape of the side surface 4c of the sealing layer 4 is formed.

In this way, the circuit module 200 is produced. Also in this embodiment, it is possible to achieve the same operation and effect as those in the first embodiment. According to this embodiment, because the first shield portion 251 has the tapered shape from the main surface 4a of the sealing layer 4 toward the uneven surface portion 2c, it is possible to easily fill the conductive resin in the cut groove 2C and to increase the filling amount of conductive resin while securing a large mounting area of components. Accordingly, it is possible to prevent an electromagnetic wave from entering and leaking from the area covered by the first shield portion 251 and the third shield portion 53 more effectively while reducing the size of the module.

Although embodiments of the present disclosure have been described, the present disclosure is not limited to the above-mentioned embodiments and various modifications can be made based on the technical ideas of the present disclosure.

For example, in this embodiment, the example in which the wiring substrate 2 includes a print wiring substrate has been described. However, the wiring substrate 2 is not limited thereto, and the wiring substrate may include a semiconductor substrate such as a silicon substrate. Moreover, the electronic component 3 may include various actuators such as MEMS (Micro Electro Mechanical System) components.

1. A circuit module, comprising:
a wiring substrate having a mount surface, the mount surface having a first area, a second area, and a third area;
a plurality of electronic components mounted on the first area, the second area, and the third area;
an insulating sealing layer having a main surface and a side surface, the insulating sealing layer covering the plurality of electronic components, the main surface having a trench, the trench being sequentially formed along a boundary between the first area, the second area, and the third area so as to be diverged en route, the trench having a tapered shape toward the mount surface, the side surface being formed around the main surface; and
a conductive shield having a first shield portion and a second shield portion, the conductive shield including conductive resin, the first shield portion covering the side surface of the sealing layer, the first shield portion having a first thickness, the second shield portion being provided in the trench, the second shield portion having a second thickness larger than the first thickness at a height of half the total height of the second shield portion,
wherein the wiring substrate further has a conductor pattern formed on the mount surface, the conductor pattern being formed along the boundary between the first area, the second area, and the third area, and
the trench has a maximum depth corresponding to a distance between the main surface and a surface of the conductor pattern.

2. The circuit module according to claim 1, wherein
the first shield portion has a uniform thickness in a height direction.

3. The circuit module according to claim 1, wherein
the first shield portion has a tapered shape toward the mount surface, and
the first thickness is a width at a height of half the total height of the first shield portion.

4. The circuit module according to claim 1, wherein
the conductive shield further has a third shield portion covering the main surface, the third shield portion being connected to the first shield portion and the second shield portion.

5-6. (canceled)

7. A method of producing a circuit module, comprising:
preparing a wiring substrate having a mount surface, the mount surface having a first area, a second area, and a third area;
mounting electronic components on the first area, the second area, and the third area;
forming a sealing layer including an insulating material on the mount surface, the sealing layer covering the electronic components;
forming, by scanning irradiation of a laser beam on a surface of the sealing layer, a trench having a tapered shape toward the mount surface, the trench being sequentially formed along a boundary between the first area, the second area, and the third area so as to be diverged en route; and
forming, by filling conductive resin in the trench and covering an outer surface of the sealing layer with the conductive resin, a conductive shield having a first shield portion and a second shield portion, the conductive shield including conductive resin, the first shield portion covering a side surface of the sealing layer, the first shield portion having a first thickness, the second shield portion being provided in the trench, the second shield portion having a second thickness larger than the first thickness at a height of half the total height of the second shield portion.
